(19) United States
(12) Patent Application Publication
(10) Pub. No.: US 2026/0112397 A1
(43) Pub. Date: Apr. 23, 2026

(54) CLOCK LEVELING FOR MEMORY INTERFACES

(71) Applicant: QUALCOMM Incorporated, San Diego, CA (US)

(72) Inventors: Patrick ISAKANIAN, El Dorado Hills, CA (US); Boris Dimitrov ANDREEV, San Diego, CA (US); Jaseem AHAMMED, San Marcos, CA (US)

(21) Appl. No.: 18/919,598

(22) Filed: Oct. 18, 2024

(51) Int. Cl. G11C 7/10; H03K 5/125

(52) U.S. Cl. CPC G11C 7/1093; H03K 5/125

(57) ABSTRACT

Various aspects of the present disclosure generally relate to memory devices. In some aspects, a device may generate a clock signal for a memory interface. The device may apply a clock leveling to one or more initial clock pulses associated with the clock signal. The device may stop the clock leveling for one or more remaining clock pulses associated with the clock signal. Numerous other aspects are described.

### FIELD OF THE DISCLOSURE

Aspects of the present disclosure generally relate to memory systems and specifically, to techniques and apparatuses for clock leveling for memory interfaces.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value. To store information, an electronic device may write to, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source.

### SUMMARY

Some aspects described herein relate to a device comprising one or more components configured to: generate a clock signal for a memory interface; apply a clock leveling to one or more initial clock pulses associated with the clock signal; and stop the clock leveling for remaining one or more clock pulses associated with the clock signal.

Some aspects described herein relate to a method comprising: generating, by a device, a clock signal for a memory interface; applying, by the device, a clock leveling to one or more initial clock pulses associated with the clock signal; and stopping, by the device, the clock leveling for one or more remaining clock pulses associated with the clock signal.

Some aspects described herein relate to an apparatus comprising: means for generating a clock signal for a memory interface; means for applying, to the clock signal, a clock leveling to one or more initial clock pulses associated with the clock signal; and means for stopping the clock leveling for one or more remaining clock pulses associated with the clock signal.

Aspects generally include a method, apparatus, system, computer program product, non-transitory computer-readable medium, memory device, or processing system as substantially described with reference to and as illustrated by the drawings and specification.

The foregoing has outlined rather broadly the features and technical advantages of examples according to the disclosure in order that the detailed description that follows may be better understood. Additional features and advantages will be described hereinafter. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages, will be better understood from the following description when considered in connection with the accompanying figures. Each of the figures is provided for the purposes of illustration and description, and not as a definition of the limits of the claims.

While aspects are described in the present disclosure by illustration to some examples, those skilled in the art will understand that such aspects may be implemented in many different arrangements and scenarios. Techniques described herein may be implemented using different platform types, devices, systems, shapes, sizes, and/or packaging arrangements. For example, some aspects may be implemented via integrated chip embodiments or other non-module-component based devices (e.g., end-user devices, vehicles, communication devices, computing devices, industrial equipment, retail/purchasing devices, medical devices, and/or artificial intelligence devices). Aspects may be implemented in chip-level components, modular components, non-modular components, non-chip-level components, device-level components, and/or system-level components. Devices incorporating described aspects and features may include additional components and features for implementation and practice of claimed and described aspects. For example, transmission and reception of wireless signals may include one or more components for analog and digital purposes (e.g., hardware components including antennas, radio frequency (RF) chains, power amplifiers, modulators, buffers, processors, interleavers, adders, and/or summers). It is intended that aspects described herein may be practiced in a wide variety of devices, components, systems, distributed arrangements, and/or end-user devices of varying size, shape, and constitution.

### BRIEF DESCRIPTION OF THE DRAWINGS

So that the above-recited features of the present disclosure can be understood in detail, a more particular description, briefly summarized above, may be had by reference to aspects, some of which are illustrated in the appended drawings. It is to be noted, however, that the appended drawings illustrate only some typical aspects of this disclosure and are therefore not to be considered limiting of its scope, for the description may admit to other equally effective aspects. The same reference numbers in different drawings may identify the same or similar elements.

FIG. 1 is a diagram illustrating an example system associated with clock leveling.

FIG. 2 is a diagram of example components included in a memory device.

FIGS. 3A-3B are diagrams illustrating examples associated with a memory system, in accordance with the present disclosure.

FIG. 4 is a diagram illustrating an example associated with clock pulse distortion, in accordance with the present disclosure.

FIG. 5 is a diagram illustrating an example associated with clock leveling, in accordance with the present disclosure.

FIG. 6 is a diagram illustrating an example associated with clock leveling, in accordance with the present disclosure.

FIG. 7 is a diagram illustrating an example associated with de-emphasis for leveling applications, in accordance with the present disclosure.

FIG. 8 is a diagram illustrating an example associated with de-emphasis for leveling applications, in accordance with the present disclosure.

FIG. 9 is a diagram illustrating an example associated with hybrid leveling, in accordance with the present disclosure.

FIG. 10 is a diagram illustrating an example associated with clock leveling circuitry, in accordance with the present disclosure.

FIGS. 11A-11C are diagrams illustrating examples associated with clock leveling circuitry, in accordance with the present disclosure.

FIG. 12 is a flowchart of an example method associated with clock leveling for memory interfaces.

### DETAILED DESCRIPTION

Low power double data rate (LPDDR) memory is a type of dynamic random access memory (RAM) (DRAM) memory designed for devices that require low power consumption, such as smartphones, tablets, laptops, and other portable devices. LPDDR memory may provide reduced voltage levels compared to standard double data rate (DDR) memory. With LPDDR memory, data may be transferred on both a rising edge and a falling edge of a clock signal.

LPDDR memory is rapidly moving toward higher data rates and clock speeds. A clock speed, which may refer to a frequency at which a memory clock oscillates, may determine a timing for data transfers. A data rate may refer to a total number of data transfers that can occur per second. The data rate may refer to a speed at which data can be read from or written to memory. A higher clock speed may result in a higher data rate.

“LPDDR interface” may refer to electrical and physical connections between a memory and a controller. The memory may be one or more LPDDR memory modules. The controller may be a dedicated memory controller or a processor. The LPDDR interface may be defined using standards and protocols that govern the transfer of data, the issue of commands, and/or power management. The LPDDR interface may include a data bus. The data bus may include multiple data lines, such as data queue (DQ) pins, that transfer data between the memory and the controller. A width of the data bus may affect an amount of data that is able to be transferred per clock cycle. The LPDDR interface may include an address and command bus (CA pins). The address and command bus may be responsible for sending commands (e.g., read, write, or refresh commands) and memory addresses from the controller to the memory. The address and command bus may determine which memory cells to access. The LPDDR interface may include clock signals (CK pins). The LPDDR interface may use differential clock signals (CK and CK#) to synchronize data transfers between the memory and the controller. The LPDDR interface may include control signals. The control signals, such as chip select (CS), row address strobe (RAS), column address strobe (CAS), and write enable (WE), may be used to coordinate various memory operations.

As the LPDDR interface is designed to support increasing speeds (e.g., higher clock speeds and/or higher data rates), the LPDDR interface may become associated with clock pulse distortion. “Clock pulse distortion” may refer to an alteration or deviation from an ideal shape, timing, or characteristics of a clock signal. Since the clock signal (or clock pulse) may be used to synchronize data transfers and operations, the clock pulse distortion may lead to errors, reduced performance, and/or system instability. With the clock pulse distortion, a first clock pulse at the memory may suffer from duty cycle distortion, which may be due to settling of a first clock pulse relative to subsequent clock pulses. The duty cycle distortion may occur when a high state and a low state of the clock signal are not of equal duration, where the duty cycle distortion may result in timing errors, reduced data transfer rates, increased power consumption, and/or signal integrity degradation. The clock pulse distortion may degrade an overall system performance. With increasing data rates, the LPDDR interface may suffer from first clock pulse distortion, which may limit a system margin and performance.

Various aspects relate generally to clock leveling for memory interfaces. In some aspects, a device (e.g., an LPDDR device), via one or more components, may generate a clock signal for a memory interface. The memory interface may be an LPDDR interface. The clock signal may be a true clock signal or a complementary clock signal. The device, via the one or more components, may apply a clock leveling to one or more initial clock pulses associated with the clock signal. In one example, the device may apply the clock leveling to only a first clock pulse associated with the clock signal. The device, via the one or more components, may stop the clock leveling for one or more remaining clock pulses associated with the clock signal. The device may not apply the clock leveling to the remaining clock pulses associated with the clock signal. The clock leveling may reduce a peak voltage level associated with the clock signal to allow a faster zero crossing for the clock signal, as compared to when the peak voltage level is not reduced using the clock leveling. The faster zero crossing may reduce or remove a clock pulse distortion associated with the one or more initial clock pulses. The device, to apply the clock leveling, may depress a voltage level associated with the clock signal during the one or more initial clock pulses, where an amount of the voltage level depression may be associated with an amount of de-emphasis.

In some aspects, the clock leveling may be employed to overcome the clock pulse distortion associated with the initial clock pulses (e.g., the first clock pulse). An edge controller may be used to control the clock leveling. The clock leveling may help a far end receiver by altering the time to a zero crossing, which may help to remove the clock pulse distortion. The clock leveling may be used to address and correct timing mismatches or signal integrity issues that arise from variations in clock signals. The clock leveling may involve adjusting or compensating for differences or variations in the clock signal to ensure that a consistent and correctly-timed clock signal is produced. By implementing the clock leveling, the clock signal may reach a target duty cycle in a shorter amount of time, as compared to when the clock leveling is not implemented. When the clock signal reaches the target duty cycle in the shorter amount of time, a first one or two cycles of the clock signal may not be wasted.

In some aspects, the clock leveling may be provided at a transmitter of the device. The clock leveling may not require equalization (EQ) segments (e.g., sections of a signal path in which equalization techniques are applied to correct signal distortions). The clock leveling may not involve additional pad capacitance at a pad to provide functionality. The clock leveling may be based at least in part on a front-end multiplexing in a pre-driver. The clock leveling may serve to remove pulse distortion, which may increase system margins. The clock leveling may use a temporary de-emphasis to provide relief for the far end receiver.

Particular aspects of the subject matter described in this disclosure can be implemented to realize one or more of the following potential advantages. In some examples, by implementing clock leveling at the device, a clock pulse distortion associated with initial clock pulses may be removed. The clock pulse distortion associated with the initial clock pulses may arise from a duty cycle distortion, which may be due to settling of the initial clock pulses relative to subsequent clock pulses. Removing the clock pulse distortion may ensure that a clock signal is uniform and stable across different components or regions, which may help to prevent timing errors and ensure that data is reliably transferred and processed. As a result, employing the clock leveling may improve an overall system performance.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. One skilled in the art should appreciate that the scope of the disclosure is intended to cover any aspect of the disclosure disclosed herein, whether implemented independently of or combined with any other aspect of the disclosure. For example, an apparatus may be implemented, or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

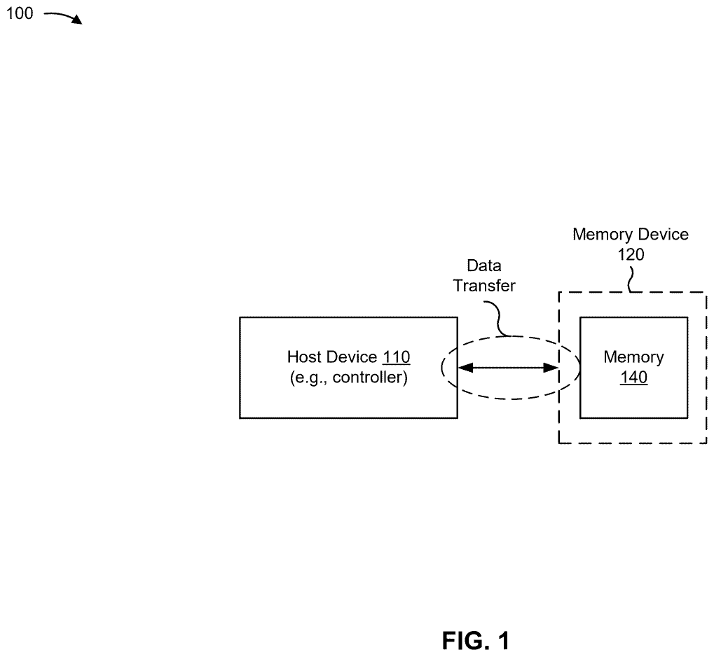

FIG. 1 is a diagram illustrating an example system 100 associated with clock leveling for the system 100. The system 100 may include one or more devices, apparatuses, and/or components for performing operations described herein. For example, the system 100 may include a host device 110 (e.g., a controller or memory controller) and a memory device 120. The memory device 120 may include memory 140. The host device 110 may communicate with the memory device 120 via an interface.

In some implementations, one or more systems, devices, apparatuses, components, and/or controllers of FIG. 1 may be configured to generate a clock signal for a memory interface; apply a clock leveling to one or more initial clock pulses associated with the clock signal; and stop the clock leveling for one or more remaining clock pulses associated with the clock signal.

The system 100 may be any electronic device configured to store data in memory. For example, the system 100 may be a computer, a mobile phone, a wired or wireless communication device, a network device, a server, a device in a data center, a device in a cloud computing environment, a vehicle (e.g., an automobile or an airplane), and/or an Internet of Things (IoT) device. The host device 110 may include one or more processors configured to execute instructions and store data in the memory 140. For example, the host device 110 may include a central processing unit (CPU), a graphics processing unit (GPU), a field-programmable gate array (FPGA), an application-specific integrated circuit (ASIC), and/or another type of processing component.

The memory device 120 may be any electronic device configured to store data in memory. In some implementations, the memory device 120 may be an electronic device configured to store data temporarily in volatile memory. For example, the memory device 120 may be a RAM device, such as a DRAM device or a static RAM (SRAM) device. The DRAM device may include an LPDDR memory. In this case, the memory 140 may include volatile memory that requires power to maintain stored data and that loses stored data after the memory device 120 is powered off. For example, the memory 140 may include one or more latches and/or RAM, such as DRAM and/or SRAM.

The host device 110 may be any device configured to control operations of the memory device 120. For example, the host device 110 may include control logic, a memory controller, a system controller, an ASIC, an FPGA, a processor, a microcontroller, and/or one or more processing components.

As indicated above, FIG. 1 is provided as an example. Other examples may differ from what is described with regard to FIG. 1.

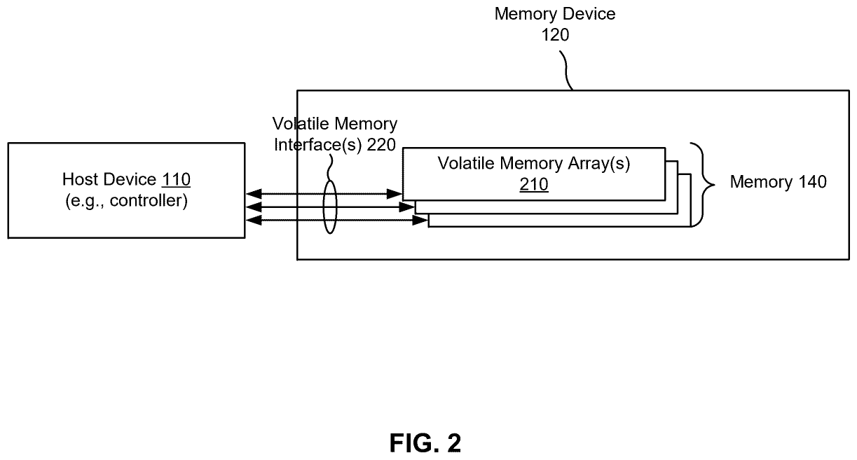

FIG. 2 is a diagram of example components included in a memory device 120. As described above in connection with FIG. 1, the memory device 120 may include memory 140. As shown in FIG. 2, the memory 140 may include one or more volatile memory arrays 210, such as one or more SRAM arrays and/or one or more DRAM arrays. A host device 110 may transmit signals to and receive signals from a volatile memory array 210 using a volatile memory interface 220.

The host device 110 may control operations of the memory 140, such as by executing one or more instructions. For example, the memory device 120 may store one or more instructions in the memory 140 as firmware, and the host device 110 may execute the one or more instructions. In some implementations, a non-transitory computer-readable medium (e.g., volatile memory and/or non-volatile memory) may store a set of instructions (e.g., one or more instructions or code) for execution by the host device 110. The host device 110 may execute the set of instructions to perform one or more operations or methods described herein. In some implementations, execution of the set of instructions, by the host device 110, causes the host device 110 and/or the memory device 120 to perform one or more operations or methods described herein. In some implementations, hardwired circuitry is used instead of or in combination with the one or more instructions to perform one or more operations or methods described herein. Additionally, or alternatively, the host device 110 and/or one or more components of the memory device 120 may be configured to perform one or more operations or methods described herein. An instruction is sometimes called a “command.”

The number and arrangement of components shown in FIG. 2 are provided as an example. In practice, there may be additional components, fewer components, different components, or differently arranged components than those shown in FIG. 2. Furthermore, two or more components shown in FIG. 2 may be implemented within a single component, or a single component shown in FIG. 2 may be implemented as multiple, distributed components. Additionally, or alternatively, a set of components (e.g., one or more components) shown in FIG. 2 may perform one or more operations described as being performed by another set of components shown in FIG. 2.

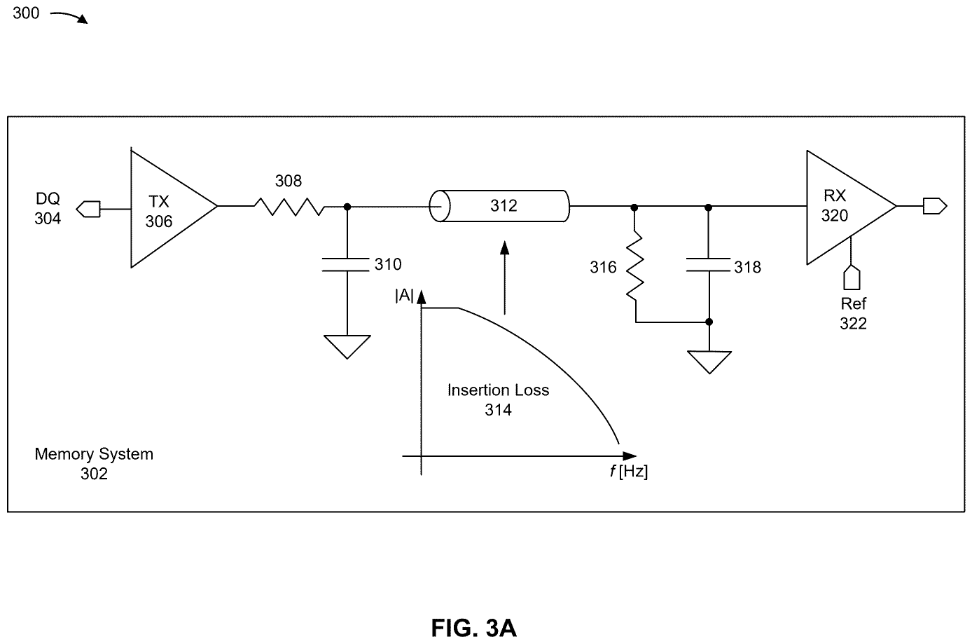

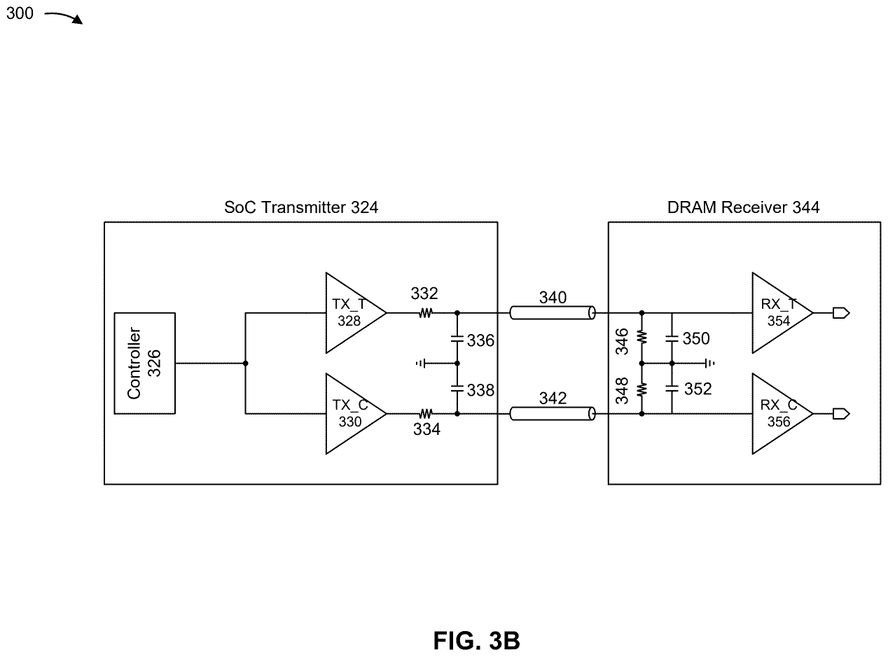

FIGS. 3A and 3B are diagrams illustrating examples 300 associated with a memory system, in accordance with the present disclosure.

As shown in FIG. 3A, a memory system 302 may include a DQ pin 304, a transmitter (TX) 306, a first resistor 308, a first capacitor 310, an impedance (Z) 312 associated with a serial link of the memory system 302, a second resistor 316, a second capacitor 318, a receiver (RX) 320, and a reference pin 322. The DQ pin 304 may be coupled to the transmitter 306. The first resistor 308, the second resistor 316, the first capacitor 310, and the second capacitor 318 may be associated with defined resistive and capacitive values, respectively. The serial link may be associated with an insertion loss 314 (or channel loss) and parasitics. The parasitics may refer to any unwanted signal on the serial link which may contribute to the insertion loss 314. The insertion loss may be in terms of amplitude (A) and frequency (in Hertz (Hz)). The reference pin 322 may be coupled to the receiver 320. The DQ pin 304 (e.g., dq0 or another pin) may be associated with the serial link between the transmitter 306 and the receiver 320 of the memory system 302. The serial link may be used to convey signals from the transmitter 306 to the receiver 320, where the signals may be associated with different voltages. The DQ pin 304, the transmitter 306, the first resistor 308, and/or the first capacitor 310 may be associated with a controller (e.g., host device 110). The second resistor 316, the second capacitor 318, and/or the receiver 320 may be associated with a memory (e.g., memory 140).

As shown in FIG. 3B, the memory system 304 may include a system-on-chip (SoC) transmitter 324 and a DRAM receiver 344. The SoC transmitter 324 may include a controller 326. The SoC transmitter 324 may include a first transmitter 328 (TX_T) associated with a true clock signal, a resistor 332, and a capacitor 336. The SoC transmitter 324 may include a second transmitter 330 (TX_T) associated with a complementary clock signal, a resistor 334, and a capacitor 338. The DRAM receiver 344 may include a first receiver 354 (RX_T) associated with the true clock signal, a resistor 346, and a capacitor 350. The DRAM receiver 344 may include a second receiver 356 (RX_C) associated with the complementary clock signal, a resistor 348, and a capacitor 352. The first transmitter 328 may be coupled to the first receiver 354 via a serial link associated with an impedance 340. The second transmitter 330 may be coupled to the second receiver 356 via a serial link associated with an impedance 342.

As indicated above, FIGS. 3A-3B are provided as examples. Other examples may differ from what is described with regard to FIGS. 3A-3B.

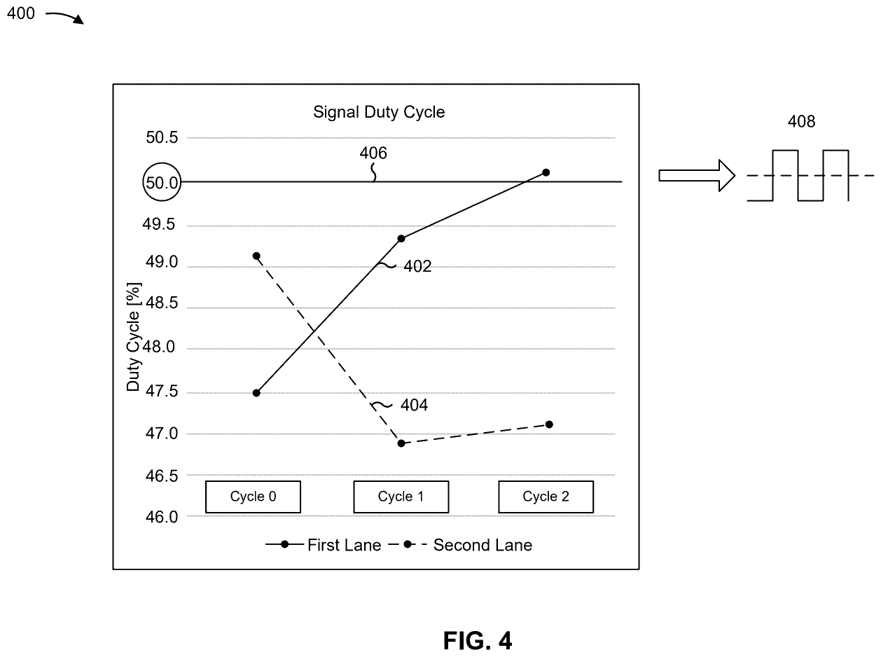

FIG. 4 is a diagram illustrating an example 400 associated with clock pulse distortion, in accordance with the present disclosure.

As shown in FIG. 4, in a memory system (e.g., as shown in FIG. 3), a target duty cycle 406 for a clock signal traveling on a serial link may be set to 50%. For example, the clock signal may be a write clock (WCK) signal. The target duty cycle 406 may refer to a high voltage state and a low voltage state associated with the signal. When the target duty cycle 406 is set to 50%, the clock signal may be in the high voltage state 50% of the time and the clock signal may be in the low voltage state 50% of the time (e.g., as shown by reference number 408). A rising edge and a falling edge of the signal may be such that the clock signal maintains a 50-50 split between the high voltage state and the low voltage state. The target duty cycle 406 of 50% may be an ideal duty cycle for the memory system. Clock signals may travel on the serial link via one or more lanes. A lane may be a path that carries a clock signal (e.g., data may be transmitted on both a rising edge and a falling edge of the clock signal), and the target duty cycle 406 of 50% may be applicable to each lane.

In this example, the memory system may include a first lane and a second lane. The first lane may be associated with a true clock signal and the second lane may be associated with a complementary clock signal. In the first lane, at a beginning time (cycle 0) a clock signal 402 (e.g., preamble) may have a duty cycle of approximately 47.5% (meaning that the clock signal 404 does not equally split time between a high state and a low state). The clock signal 402, after one cycle, may have a duty cycle of approximately 49.5%. The clock signal 402, after two cycles, may have a duty cycle of approximately 50%. The clock signal 402 may take up to two cycles before reaching the target duty cycle 406 of 50%. In the second lane, at a beginning time (cycle 0), a clock signal 404 (e.g., preamble) may have a duty cycle of approximately 49%. The clock signal 404, after one cycle, may have a duty cycle of approximately 47%. The clock signal 404, after two cycles, may have a duty cycle of approximately 47%. The clock signal 404 may take more than two cycles before reaching the target duty cycle 406 of 50%. An amount of time needed to reach the target duty cycle 406 of 50% may be a result of clock pulse distortion, which may be associated with a first clock pulse (or several initial clock pulses). Further, the first lane may behave differently from the second lane, even though the first lane and the second lane may be associated with a same transmitter (e.g., transmitter 306). During the clock pulse distortion, clocks may experience a duty cycle distortion, which may be a pulse distortion away from an ideal value. An insertion loss, brought about by parasitic loading, may induce the clock pulse distortion at higher data rates. A few cycles may be needed for clock pulses to reach a settled behavior, absent any corrective action.

As indicated above, FIG. 4 is provided as an example. Other examples may differ from what is described with regard to FIG. 4.

In some aspects, clock leveling may be used to overcome clock pulse distortion. The clock leveling may be based at least in part on a voltage mode leveling and/or a current mode leveling (e.g., a hybrid architecture). The clock leveling may include a top side leveling and/or a bottom side leveling. The top side leveling may reduce a peak voltage level associated with a clock signal, which may allow for the clock signal (e.g., a first clock pulse associated with the clock signal) to have a faster zero crossing, as compared to when the clock leveling is not employed. The faster zero crossing may serve to remove distortion associated with the clock signal. A reduction in the peak voltage level may be associated with a de-emphasis, where the de-emphasis may be associated with a depressed or lowered voltage. An amount of distortion removed may be directly correlated to an amount of de-emphasis. The top side leveling may be employed for a true clock signal. The bottom side leveling may be similar to the top side leveling, but a direction may be swapped, as compared to the top side leveling. The bottom side leveling may be employed for a complementary clock signal.

In some aspects, the clock leveling may be de-asserted following the first clock pulse. The clock leveling may be employed for an LPDDR interface, where an impedance of the LPDDR interface is to remain constant. Further, the clock leveling may allow for a leading clock edge to pass the zero crossing earlier in time, which may serve to remove the distortion.

In some aspects, a clock interface (true and complementary) may be de-emphasized prior to a start of toggles. The de-emphasis may be removed after a first edge is present. When the de-emphasis is removed during a proper transition, a glitch-free operation may be obtained. The de-emphasis may allow for the faster zero crossing of a first edge, which may reduce or remove a duty cycle distortion. In a clock signal waveform, de-emphasis may be applied prior to clock pulses, which may be followed by full swing toggles. The de-emphasis may be applied to true clock signals (CLK_T) and complementary clock signals (CLK_C). True and complementary clocks may require opposite polarity corrections.

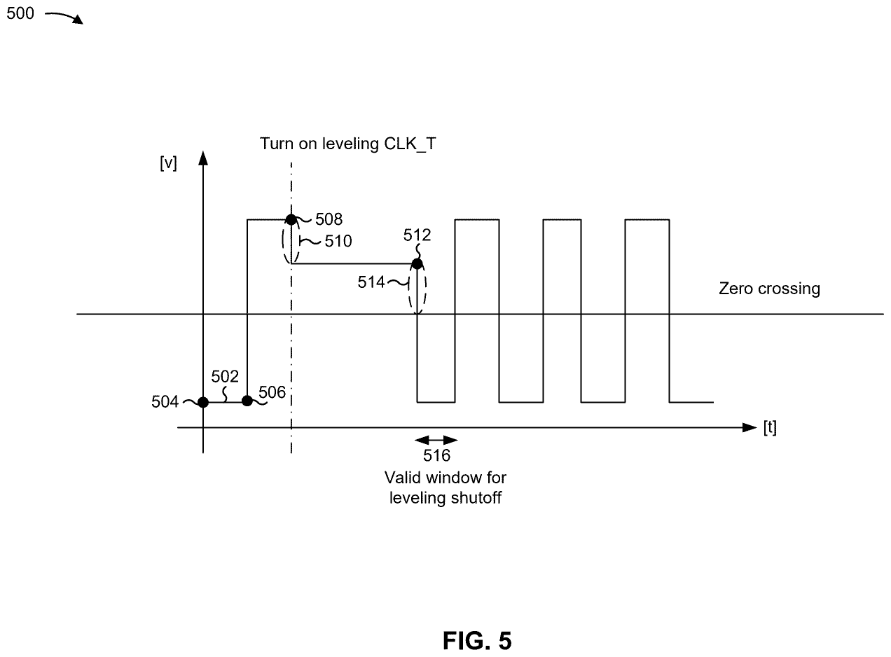

FIG. 5 is a diagram illustrating an example 500 associated with clock leveling, in accordance with the present disclosure.

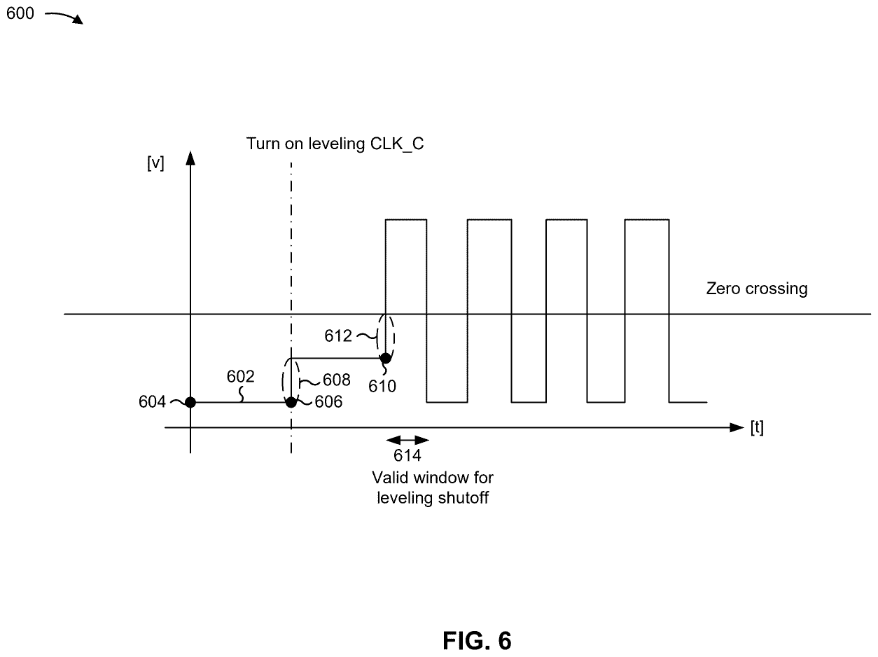

As shown in FIG. 5, for a high-speed clock interface, a clock signal 502 (CLK_T) may travel over a serial link of a memory system (e.g., memory system 302). The clock signal 502 may be a true clock signal. The true clock signal may be a primary clock signal used for synchronization. The clock signal 502 may be associated with a given voltage over a period of time. At a start time 504, the clock signal 502 may be associated with a low voltage state. At a time 506, the clock signal 502 may transition from the low voltage state to a high voltage state. The clock signal 502 may remain at the high voltage state until time 508, at which a clock leveling may be applied to the clock signal 502. The clock leveling may be turned on, which may cause a voltage depression or de-emphasis on the clock signal 502 (as shown by reference number 510). “Voltage depression” or “de-emphasis” may refer to a change in voltage associated with the clock signal 502. In this example, the change in voltage may be a reduction in voltage for the clock signal 502. In another example (e.g., as shown in FIG. 6), the change in voltage may be an increased voltage. An amount of voltage depression or de-emphasis (e.g., increased or decreased voltage) may be a configurable parameter. De-emphasis, pre-distortion, and voltage depression may all refer to the same waveform manipulation. The clock signal 502 may remain at a high depressed voltage for a duration of time, and at time 512, the clock signal 502 may transition to the low voltage state. Since the clock signal 502 is already at the high depressed voltage, the clock signal 502 may reach the low voltage state in a shorter period of time, as compared to if the clock signal 502 is at the high voltage state. The clock signal 502, by being at the high depressed voltage, may achieve a faster zero crossing (as shown by reference number 514). At time 512, a valid window 516 for leveling shutoff may be defined. The clock leveling may be stopped during this valid window 516. After the valid window 516, the clock signal 502 may be associated with a duty cycle of approximately 50%. The clock leveling may be a top side leveling, where the top side leveling may be associated with the true clock signal. By applying the clock leveling, a first clock pulse associated with the clock signal 502 may have the faster zero crossing. The faster zero crossing may be due to the depressed voltage associated with the clock signal 502, which may allow for the zero crossing to be reached in a shorter amount of time, as compared to a non-depressed voltage. The faster zero crossing may result in a removal of distortion from the clock signal 502.

As indicated above, FIG. 5 is provided as an example. Other examples may differ from what is described with regard to FIG. 5.

FIG. 6 is a diagram illustrating an example 600 associated with clock leveling, in accordance with the present disclosure.

As shown in FIG. 6, for a high-speed clock interface, a clock signal 602 (CLK_C) may travel over a serial link of a memory system (e.g., memory system 302). The clock signal 602 may be a complimentary clock signal. The complimentary clock signal (inverted clock signal) may be derived from a true clock signal and may represent an opposite state of the true clock signal. The clock signal 602 may be associated with a given voltage over a period of time. At a start time 604, the clock signal 602 may be associated with a low voltage state. At a time 606, a clock leveling may be applied to the clock signal 602. The clock leveling may be turned on, which may cause a voltage depression or de-emphasis on the clock signal 602 (as shown by reference number 608). “Voltage depression” or “de-emphasis” may refer to a change in voltage associated with the clock signal 602. In this example, the change in voltage may be an increase in voltage for the clock signal 602. An amount of voltage depression or de-emphasis may be a configurable parameter. The clock signal 602 may remain at a low depressed voltage for a duration of time, and at time 610, the clock signal 602 may transition to a high voltage state. Since the clock signal 602 is already at the low depressed voltage, the clock signal 602 may reach the high voltage state in a shorter period of time, as compared to if the clock signal 602 is at the low voltage state. The clock signal 602, by being at the low depressed voltage, may achieve a faster zero crossing (as shown by reference number 612). At time 614, a valid window for leveling shutoff may be defined. The clock leveling may be stopped during this valid window 614. After the valid window 614, the clock signal 602 may be associated with a duty cycle of approximately 50%. The clock leveling may be a bottom side leveling, where the bottom side leveling may be associated with the complimentary clock signal. By applying the clock leveling, a first clock pulse associated with the clock signal 602 may have the faster zero crossing. The faster zero crossing may be due to the depressed voltage associated with the clock signal 502, which may allow for the zero crossing to be reached in a shorter amount of time, as compared to a non-depressed voltage. The faster zero crossing may result in a removal of distortion from the clock signal 602.

As indicated above, FIG. 6 is provided as an example. Other examples may differ from what is described with regard to FIG. 6.

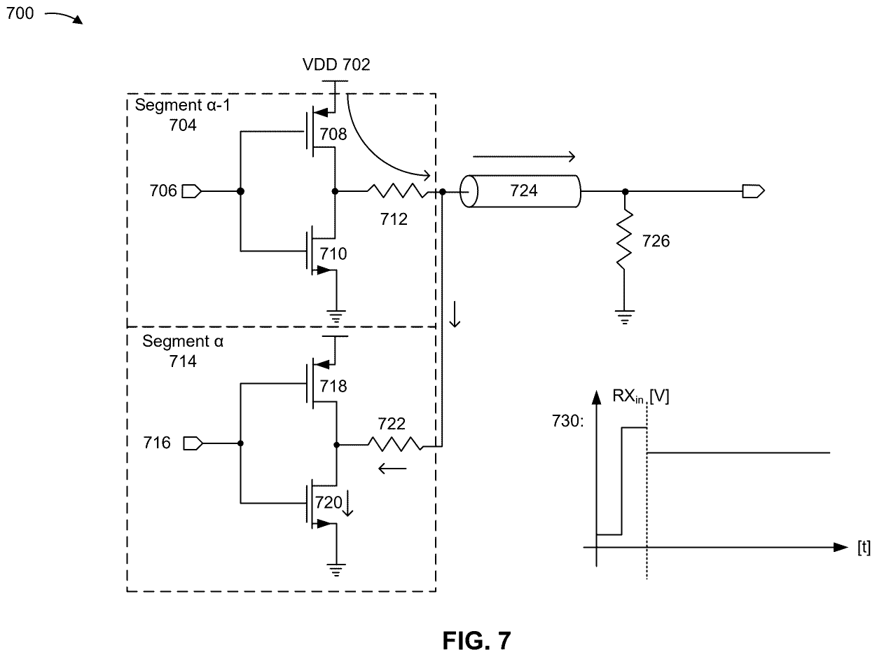

FIG. 7 is a diagram illustrating an example 700 associated with de-emphasis for leveling applications, in accordance with the present disclosure.

As shown in FIG. 7, a driver associated with a memory system (e.g., memory system 302) may be repartitioned into a first segment (segment 1-α) 704 and a second segment (α) 714. The first segment 704 may include a pin 706 (first transmit input (TXin)), a first transistor 708, a second transistor 710, and a resistor 712. The second segment 714 may include a pin 716 (second TXin), a first transistor 718, a second transistor 720, a resistor 722, and a resistor 726. A supply voltage (VDD) 702 may provide a voltage to the memory system. When a clock leveling is asserted, an amount of voltage may be directed from the first segment 704 to the second segment 714. The second segment 714 may be responsible for a voltage depression or de-emphasis. A depressed voltage (e.g., a lowered voltage) may be carried on a serial link. The serial link may be associated with an impedance (Z) 724. When the clock leveling is asserted, a clock voltage may be depressed for a certain period of time (as shown by reference number 730). When the clock leveling is no longer asserted, the second segment 714 may no longer be used. In other words, when the clock leveling is no longer asserted, the second segment 714 may be turned off so some amount of voltage may not be diverted to the second segment 714. In this example, the memory system may include one or more components to depress a voltage, where the voltage may be depressed to assert the clock leveling. When the clock leveling is asserted, not all current may be delivered to a load, but rather some of the current may be shunted off to depress the voltage at a pad. The pad may be an input/output (I/O) pad, which may include a physical interface or connection point on a memory where signals are transmitted and received. The first segment 704 and the second segment 714 may be associated with a true clock signal. For example, the true clock signal may be directed over the serial link using the first segment 704 and the second segment 714.

As indicated above, FIG. 7 is provided as an example. Other examples may differ from what is described with regard to FIG. 7.

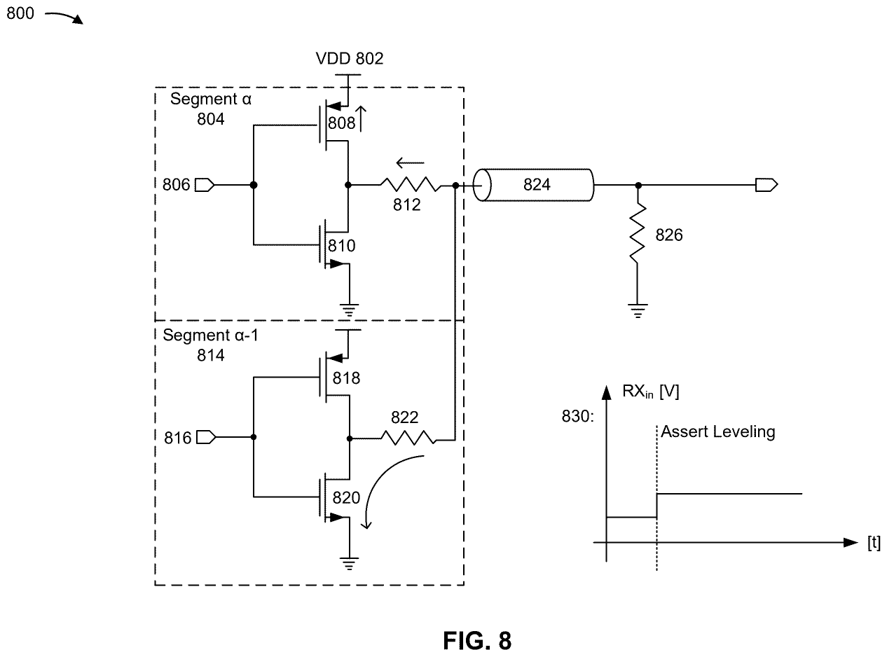

FIG. 8 is a diagram illustrating an example 800 associated with de-emphasis for leveling applications, in accordance with the present disclosure.

As shown in FIG. 8, a driver associated with a memory system (e.g., memory system 302) may be repartitioned into a first segment (segment α) 804 and a second segment (segment 1-α) 814. The first segment 804 may include a pin 806 (first TXin), a first transistor 808, a second transistor 810, a resistor 812, and a resistor 826. The second segment 814 may include a pin 816 (second TXin), a first transistor 818, a second transistor 820, and a resistor 822. A supply voltage (VDD) 802 may provide a voltage to the memory system. When a clock leveling is asserted, an amount of voltage may be directed from the second segment 814 to the first segment 804. The first segment 804 may be responsible for a voltage depression or de-emphasis. A depressed voltage (e.g., an increased voltage) may be carried over a serial link. The serial link may be associated with an impedance 824. When the clock leveling is asserted, a clock voltage may be depressed for a certain period of time (as shown by reference number 830). When the clock leveling is no longer asserted, the first segment 804 may no longer be used. In other words, when the clock leveling is no longer asserted, the first segment 804 may be turned off so some amount of voltage may not be diverted to the first segment 804. In this example, the memory system may include one or more components to depress a voltage, where the voltage may be depressed to assert the clock leveling. When the clock leveling is asserted, not all current may be taken from a load, but rather some of the current may be shunted off to depress the voltage taken out of a pad. The first segment 804 and the second segment 814 may be associated with a complementary clock. For example, the complementary clock signal may be directed over the serial link using the first segment 804 and the second segment 814.

As indicated above, FIG. 8 is provided as an example. Other examples may differ from what is described with regard to FIG. 8.

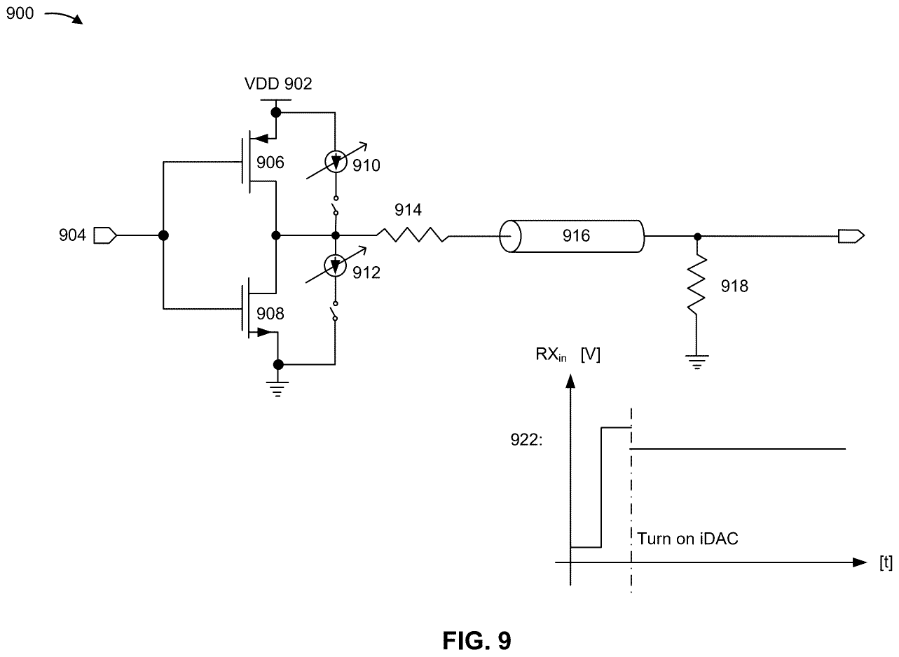

FIG. 9 is a diagram illustrating an example 900 associated with hybrid leveling, in accordance with the present disclosure.

As shown in FIG. 9, a memory system (e.g., memory system 302) may include a supply voltage (VDD) 902, a pin 904, a first transistor 906, a second transistor 908, a first current device 910, a second current device 912, a first resistor 914, a serial link associated with an impedance 916, and a second resistor 918. The first current device 910 and/or the second current device 912 may adjust an amount of current in order to assert clock leveling. For example, when a current digital-to-analog converter (IDAC) is turned on, the first current device 910 and/or the second current device 912 may be used to adjust the current for asserting the clock leveling (as shown by reference number 922). The first current device 910 and/or the second current device 912 may be responsible for a voltage depression or de-emphasis. When the clock leveling is asserted, a clock voltage may be depressed for a certain period of time. The depressed clock voltage may be carried over the serial link. When the clock leveling is no longer asserted, the first current device 910 and/or the second current device 912 may no longer be used. For example, the first current device 910 and/or the second current device 912 may be associated with respective switches, which may be used to turn on and off the first current device 910 and/or the second current device 912. The memory system may operate in a hybrid mode, in which current sources may be used to direct current into a pad or out of the pad, depending on whether the clock signal is associated with a true clock or a complementary clock, and such actions may serve to depress a peak voltage level. Such a voltage depression may cause a first clock pulse to have a faster zero crossing, which may cause distortion to be removed from the clock signal. In this example, the hybrid mode may shift a burden out of a pre-driver path, such that the hybrid mode may load a driver with a sink for a true clock signal (CLK_T) and a source for a complementary clock signal (CLK_C). A terminated leveling may be less than 50% of full scale, where such leveling may be associated with a power penalty in some modes and not in other modes.

As indicated above, FIG. 9 is provided as an example. Other examples may differ from what is described with regard to FIG. 9.

In some aspects, unlike traditional equalization, a de-emphasis may be turned off following an initial pulse, which must guarantee a glitch-free transition. Since an amount of de-emphasis may be fixed, a multiplexing associated with the de-emphasis may be simplified. In some aspects, a detector, such as an edge detector, may be used to determine when an edge has arrived. After a first edge, the de-emphasis may be turned off during a pulse high/low depending on a true clock signal or a complementary clock signal. Turning the de-emphasis off during an applicable high or low pulse may ensure the glitch-free transition.

In some aspects, in order to achieve the glitch-free operation, an initial de-emphasis may be removed following a first CLK_T transition during a low side. A de-emphasis may be employed prior to CLK_T pulses. The de-emphasis may be removed following a first CLK_T edge. Similarly, in order to achieve the glitch-free operation, an initial de-emphasis may be removed following a first CLK_C transition during a low side, where the first CLK_T transition and the first CLK_C transition may be associated with opposite polarities.

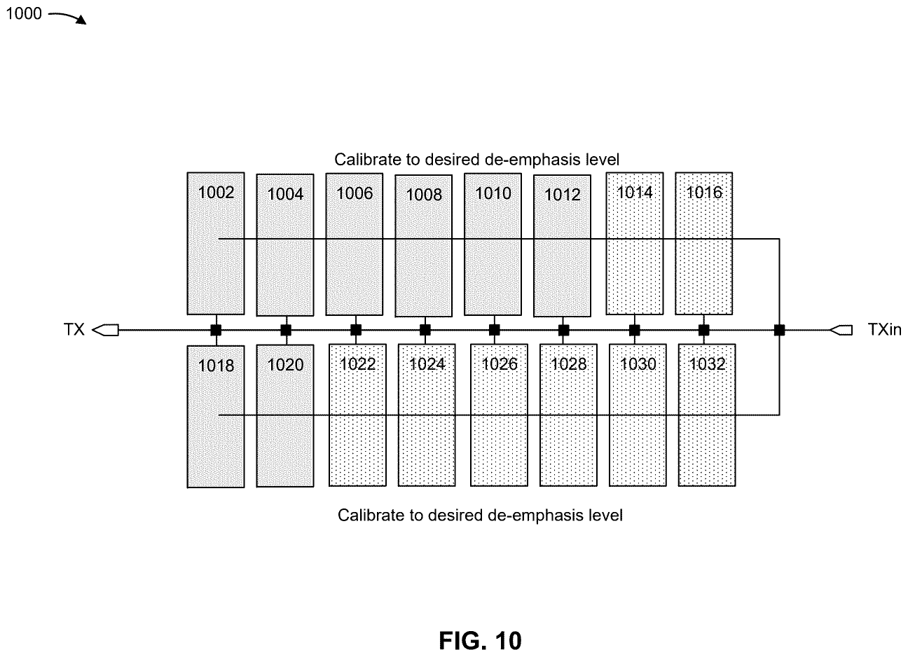

FIG. 10 is a diagram illustrating an example 1000 associated with clock leveling circuitry, in accordance with the present disclosure.

As shown in FIG. 10, a memory system (e.g., memory system 302) may include a plurality of pull up elements 1002, 1004, 1006, 1008, 1010, 1012, 1014, 1016 and a plurality of pull down elements 1018, 1020, 1022, 1024, 1026, 1028, 1030, 1032. In the memory system, some pull up elements may be turned off and corresponding pull down elements must be turned on. In other words, for every pull up elements turned off, an equivalent (or near equivalent) number of pull down elements must be turned on. The plurality of pull up elements 1002, 1004, 1006, 1008, 1010, 1012, 1014, 1016 and the plurality of pull down elements 1018, 1020, 1022, 1024, 1026, 1028, 1030, 1032 may be NMOS legs. Since a number of pull up elements and a number of pull down elements is constant, an impedance provided to an interface may be constant, which may remove any reflection based at least in part on signal loss, as well as provide for a desired amount of de-emphasis. In this example, for a top-side de-emphasis, two pull up elements 1014, 1016 may be turned off, while a two corresponding pull down elements 1018, 1020 may be turned on. Assuming that the plurality of pull up elements 1002, 1004, 1006, 1008, 1010, 1012, 1014, 1016 is equal to the plurality of pull down elements 1018, 1020, 1022, 1024, 1026, 1028, 1030, 1032, the impedance may be constant and the de-emphasis may be obtained. In this example, a calibration and transmit model may involve using one or more components to calibrate to a desired de-emphasis level. The desired de-emphasis level may impact an amount of voltage level depression. The one or more components may include the plurality of pull up elements 1002, 1004, 1006, 1008, 1010, 1012, 1014, 1016 and the plurality of pull down elements 1018, 1020, 1022, 1024, 1026, 1028, 1030, 1032, and depending on a configuration of the one or more components, the desired de-emphasis level may be set.

As indicated above, FIG. 10 is provided as an example. Other examples may differ from what is described with regard to FIG. 10.

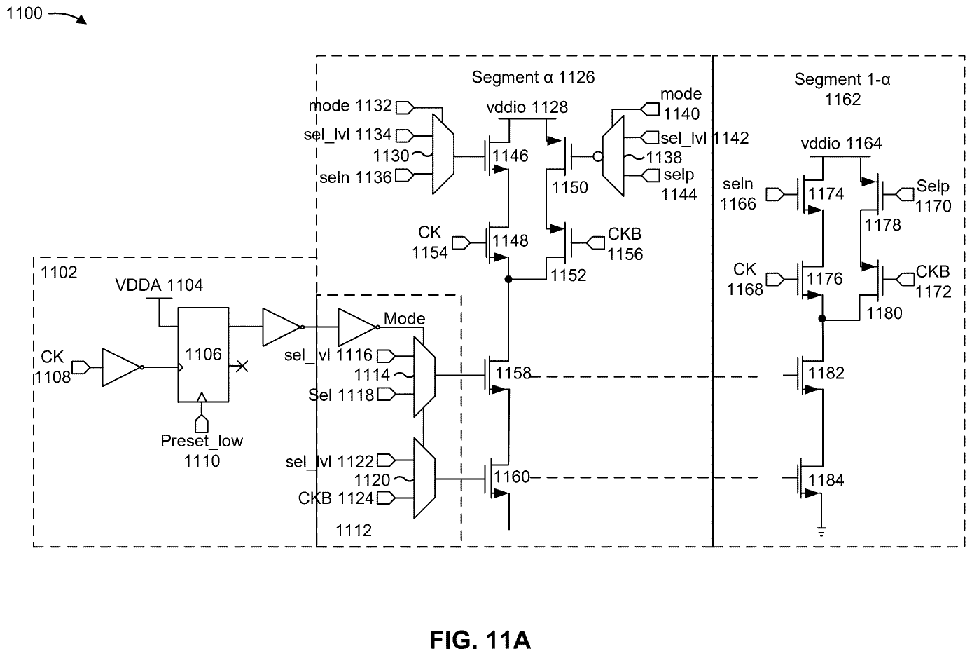

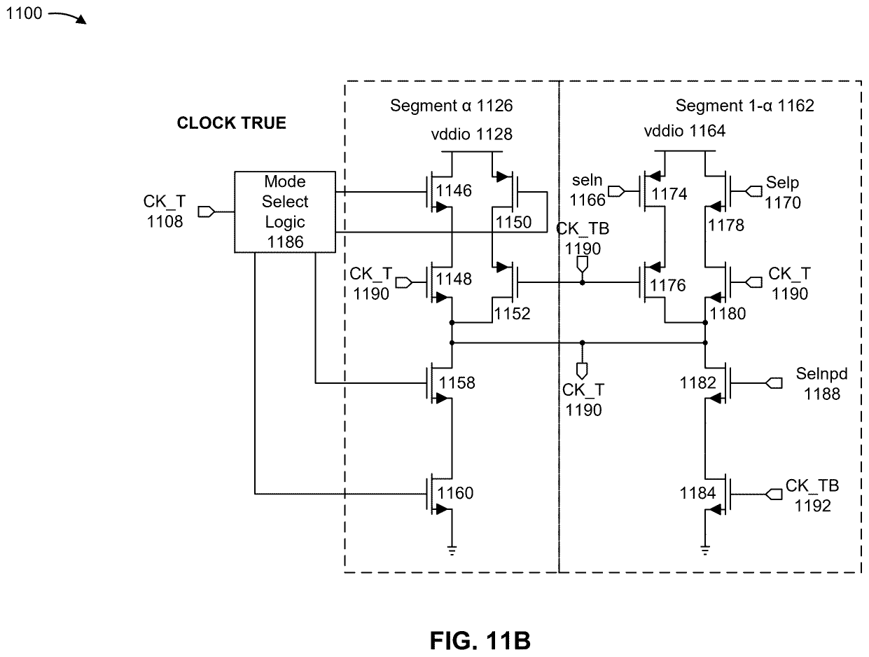

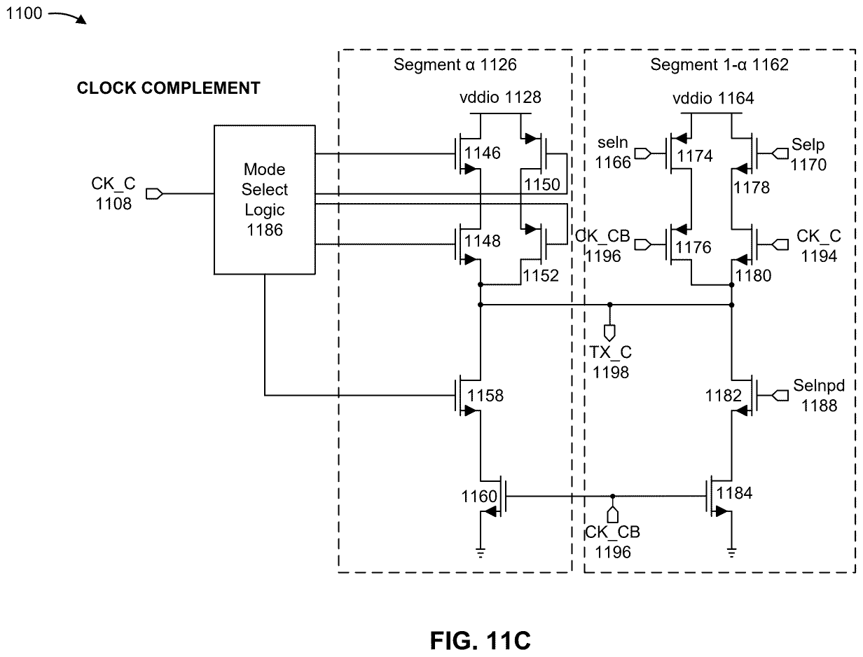

FIGS. 11A-11C are diagrams illustrating examples 1100 associated with clock leveling circuitry, in accordance with the present disclosure.

As shown in FIG. 11A, a memory system (e.g., memory system 302) may include a detector 1102, such as an edge detector. The detector 1102 may include a voltage supply (VDDA) 1104 and a multiplexer 1106. A clock signal 1108 may be inputted to the multiplexer 1106. The clock signal 1108 may be a true clock signal or a complementary clock signal. The multiplexer may include a preset low pin 1110. The multiplexer may include a variety of other pins (e.g., clock, D, and Q). The detector 1102 may be responsible for detecting an edge in the clock signal 108. The clock signal 108 may be a true clock signal or a complementary clock signal. The detector 1102 may include various other components, such as one or more amplifiers. The memory system may include a mode selection component 1112. The selection component 1114 may include a first multiplexer 1114. The first multiplexer 1114 may include a select level (sel_lvl) pin 1116 and a select (sel) pin 1118. The selection component 1114 may include a second multiplexer 1120. The second multiplexer 1120 may include a select level pin 1122 and a clock signal complement (CKB) pin 1124. The selection component 1114 may be responsible for a mode selection. The mode selection may involve using a first mode or a second mode. The first mode may involve a voltage depression or de-emphasis, and the second mode may involve no voltage depression or no de-emphasis. When the first mode is utilized, the clock signal 108 may be directed to a first segment 1126 (segment α). When the second mode is utilized, the clock signal 108 may be directed to a second segment 1162 (segment 1-α). In other words, the first segment 1126 may be associated with the first mode (voltage depression or de-emphasis), and the second segment 1162 may be associated with the second mode (no voltage depression or no de-emphasis).

In some aspects, the first segment 1126 may include a voltage source 1128 (vddio), a multiplexer 1130, and a demultiplexer 1138. The multiplexer 1130 may be associated with a mode pin 1132, a select level pin 1134, and a select (seln) pin 1136. The demultiplexer 1138 may be associated with a mode pin 1140, a select level pin 1142, and a select (selp) pin 1144. The multiplexer 1130 and the demultiplexer 1138 may have corresponding pins. The first segment 1126 may include a CK pin 1154 and a CKB pin 1156. The first segment 1126 may include a plurality of transistors, such as transistors 1146, 1148, 1150, 1152, 1158, 1160. The first segment 1126 may be utilized for clock leveling. In some aspects, the second segment 1162 may include a voltage source 1164 (vddio), a select (seln) pin 1166, a select (selp) pin 1170, a CK pin 1168, and a CKB pin 1172. The second segment 1162 may include a plurality of transistors, such as transistors 1174, 1176, 1178, 1180, 1182, 1184. The second segment 1162 may be used when the clock leveling is not applied.

In some aspects, the memory system may include a front end logic for clock leveling. In the front end logic, the detector 1102, such as the edge detector, may determine a manner of gating a split driver for clock leveling (CLK_T/CLK_C). In other words, the detector 1102 may determine which mode is to apply to the clock signal 108 (e.g., a mode with voltage depression or de-emphasis, or a mode with no voltage depression or no de-emphasis). When a first edge is detected, a normal operation may be resumed. When the first edge is detected, the normal operation (no clock leveling) may be started. As long as a transition occurs in a correct direction, no glitch may be present. A complementary version may power a pull-up element for CLK_C, which may control P-channel metal-oxide semiconductor (PMOS) devices, and which may be preferred since an implementation may be made uniform for a pull-up element and a pull-down element. A value of α may depend on a desired amount of clock leveling, where the second segment 1162 (segment 1-α) may get no additional multiplexing (no de-emphasis). In other words, a number of segments may depend on the desired amount of clock leveling For example, employing an increased number of segments may achieve an increased amount of clock leveling. Components associated with the first segment 1116 may be associated with a main driver, and components associated with the second segment 1162 may be associated with a secondary driver.

As shown in FIG. 11B, the memory system may include the first segment 1126 and the second segment 1162. When the clock signal 1108 is the true clock signal, the clock signal 1108 may be provided to a mode select logic 1186. The mode select logic 1186 may be a self-timed circuit which provides appropriate logic and voltages for leveling control, and for exiting to a normal operation (glitch-free). The mode select logic 1186 may handle all necessary signal polarities, and the mode select logic 1186 may be self-timed based at least in part on an incoming CK edge. The mode select logic 1186 may be responsible for leveling, where the leveling may be associated with one of three modes. A first mode may involve leveling up until a first edge is observed. A second mode may involve leveling until a first two incoming pulses. A third mode may involve leveling continuously. Such leveling may be extended to complementary metal-oxide-semiconductor (CMOS) and current mode logic (CML) transmitters, and may not be applicable to only to N/N drivers. The first segment 1126 may include various pins (e.g., CK_T 1190). The second segment 1162 may include various pins (e.g., select (Selnpd) 1188, CK_T 1190, and/or CK_TB 1192), which may be based at least in part on the second segment 1162 being associated with the true clock signal. CK_TB may be a complement of CK_T.

As shown in FIG. 11C, the memory system may include the first segment 1126 and the second segment 1162. When the clock signal 1108 is the complementary clock signal, the clock signal 1108 may be provided to the mode select logic 1186. The mode select logic 1186 may provide appropriate logic and voltages for leveling control, and for exiting to the normal operation (glitch-free). The mode select logic 1186 may handle all necessary signal polarities, and the mode select logic 1186 may be self-timed based at least in part on the incoming CK edge. The mode select logic 1186 may be responsible for leveling, where the leveling may be associated with one of three modes. The first mode may involve leveling up until the first edge is observed. The second mode may involve leveling until the first two incoming pulses. The third mode may involve leveling continuously. The second segment 1162 may include various pins (e.g., CK_C 1194, CK_CB 1196, and/or TX_C 1198), which may be based at least in part on the second segment 1162 being associated with the complementary clock signal. CK_CB may be a complement of CK_C.

As indicated above, FIGS. 11A-11C are provided as examples. Other examples may differ from what is described with regard to FIGS. 11A-11C.

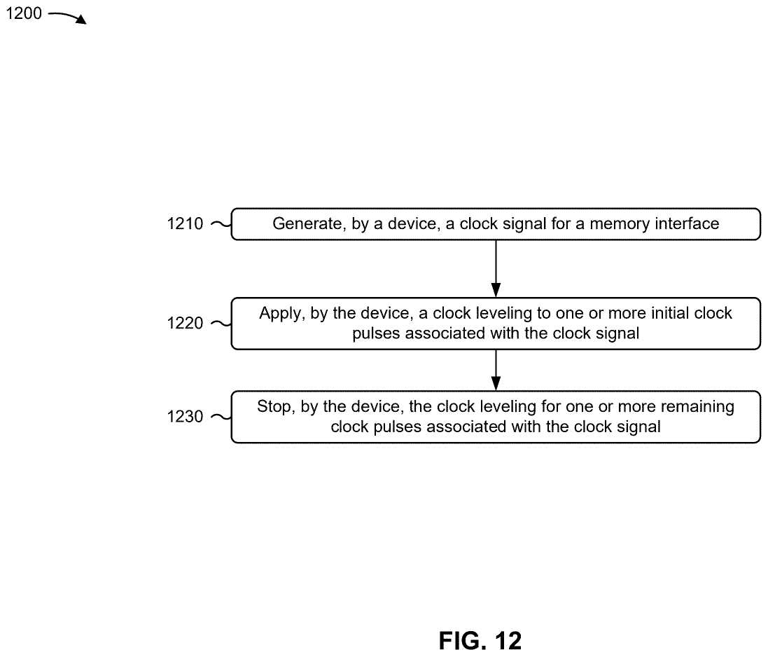

FIG. 12 is a flowchart of an example process 1200 associated with clock leveling for memory interfaces. In some implementations, one or more process blocks of FIG. 12 are performed by a device (e.g., host device 110 or memory device 120). In some implementations, one or more process blocks of FIG. 12 are performed by another device or a group of devices separate from or including the device.

As shown in FIG. 12, process 1200 may include generating a clock signal for a memory interface (block 1210). For example, the device may generate a clock signal for a memory interface, as described above.

As further shown in FIG. 12, process 1200 may include applying a clock leveling to one or more initial clock pulses associated with the clock signal (block 1220). For example, the device may apply a clock leveling to one or more initial clock pulses associated with the clock signal, as described above.

As further shown in FIG. 12, process 1200 may include stopping the clock leveling for one or more remaining clock pulses associated with the clock signal (block 1230). For example, the device may stop the clock leveling for one or more remaining clock pulses associated with the clock signal, as described above.

Process 1200 may include additional implementations, such as any single implementation or any combination of implementations described below and/or in connection with one or more other processes described elsewhere herein.

In a first implementation, the clock leveling reduces a peak voltage level associated with the clock signal to allow a faster zero crossing for the clock signal, as compared to when the peak voltage level is not reduced using the clock leveling, and the faster zero crossing reduces or removes a clock pulse distortion associated with the one or more initial clock pulses.

In a second implementation, alone or in combination with the first implementation, process 1200 includes depressing a voltage level associated with the clock signal during the one or more initial clock pulses, and an amount of the voltage level depression is associated with an amount of de-emphasis.

In a third implementation, alone or in combination with one or more of the first and second implementations, process 1200 includes stopping the clock leveling in accordance with a window for leveling shutoff.

In a fourth implementation, alone or in combination with one or more of the first through third implementations, process 1200 includes detecting, using a detector, an edge associated with the clock signal; and stopping the clock leveling, after the edge, during a pulse high or a pulse low associated with the clock signal.

In a fifth implementation, alone or in combination with one or more of the first through fourth implementations, the clock leveling is applied to only a first clock pulse associated with the clock signal, and the clock leveling is not applied to remaining clock pulses associated with the clock signal.

In a sixth implementation, alone or in combination with one or more of the first through fifth implementations, the clock leveling is applied at a transmitter of the device, and the clock leveling reduces duty cycle distortion at a receiver of the device.

In a seventh implementation, alone or in combination with one or more of the first through sixth implementations, the clock signal is a true clock signal.

In an eighth implementation, alone or in combination with one or more of the first through seventh implementations, the clock signal is a complementary clock signal.

In a ninth implementation, alone or in combination with one or more of the first through eighth implementations, the device is an LPDDR device, and the clock leveling is applied to an LPDDR memory interface associated with the LPDDR device.

Although FIG. 12 shows example blocks of process 1200, in some implementations, process 1200 includes additional blocks, fewer blocks, different blocks, or differently arranged blocks than those depicted in FIG. 12. Additionally, or alternatively, two or more of the blocks of process 1200 may be performed in parallel.

The following provides an overview of some Aspects of the present disclosure:

Aspect 1: A device, comprising: one or more components configured to: generate a clock signal for a memory interface; apply a clock leveling to one or more initial clock pulses associated with the clock signal; and stop the clock leveling for one or more remaining clock pulses associated with the clock signal.

Aspect 2: The device of Aspect 1, wherein the clock leveling reduces a peak voltage level associated with the clock signal to allow a faster zero crossing for the clock signal, as compared to when the peak voltage level is not reduced using the clock leveling, and wherein the faster zero crossing reduces or removes a clock pulse distortion associated with the one or more initial clock pulses.

Aspect 3: The device of any of Aspects 1-2, wherein the one or more components, to apply the clock leveling, are configured to: depress a voltage level associated with the clock signal during the one or more initial clock pulses, and wherein an amount of the voltage level depression is associated with an amount of de-emphasis.

Aspect 4: The device of any of Aspects 1-3, wherein the one or more components are configured to: stop the clock leveling in accordance with a window for leveling shutoff.

Aspect 5: The device of any of Aspects 1-4, wherein the one or more components, to stop the clock leveling, are configured to: detect, using a detector, an edge associated with the clock signal; and stop the clock leveling, after the edge, during a pulse high or a pulse low associated with the clock signal.

Aspect 6: The device of any of Aspects 1-5, wherein the clock leveling is applied to only a first clock pulse associated with the clock signal, and wherein the clock leveling is not applied to remaining clock pulses associated with the clock signal.

Aspect 7: The device of any of Aspects 1-6, wherein the clock leveling is applied at a transmitter of the device, and the clock leveling reduces duty cycle distortion at a receiver of the device.

Aspect 8: The device of any of Aspects 1-7, wherein the clock signal is a true clock signal.

Aspect 9: The device of any of Aspects 1-8, wherein the clock signal is a complementary clock signal.

Aspect 10: The device of any of Aspects 1-9, wherein the device is a low power double data rate (LPDDR) device, and wherein the clock leveling is applied to an LPDDR memory interface associated with the LPDDR device.

Aspect 11: A method, comprising: generating, by a device, a clock signal for a memory interface; applying, by the device, a clock leveling to one or more initial clock pulses associated with the clock signal; and stopping, by the device, the clock leveling for one or more remaining clock pulses associated with the clock signal.

Aspect 12: The method of Aspect 11, wherein the clock leveling reduces a peak voltage level associated with the clock signal to allow a faster zero crossing for the clock signal, as compared to when the peak voltage level is not reduced using the clock leveling, and wherein the faster zero crossing reduces or removes a clock pulse distortion associated with the one or more initial clock pulses.

Aspect 13: The method of any of Aspects 11-12, wherein applying the clock leveling comprises: depressing a voltage level associated with the clock signal during the one or more initial clock pulses, and wherein an amount of the voltage level depression is associated with an amount of de-emphasis.

Aspect 14: The method of any of Aspects 11-13, wherein stopping the clock leveling is in accordance with a window for leveling shutoff.

Aspect 15: The method of any of Aspects 11-14, wherein stopping the clock leveling comprises: detecting, using a detector, an edge associated with the clock signal; and stopping the clock leveling, after the edge, during a pulse high or a pulse low associated with the clock signal.

Aspect 16: The method of any of Aspects 11-15, wherein the clock leveling is applied to only a first clock pulse associated with the clock signal, and wherein the clock leveling is not applied to remaining clock pulses associated with the clock signal.

Aspect 17: The method of any of Aspects 11-16, wherein the clock leveling is applied at a transmitter of the device, and the clock leveling reduces duty cycle distortion at a receiver of the device.

Aspect 18: The method of any of Aspects 11-17, wherein: the clock signal is a true clock signal; or the clock signal is a complementary clock signal.

Aspect 19: The method of any of Aspects 11-18, wherein the device is a low power double data rate (LPDDR) device, and wherein the clock leveling is applied to an LPDDR memory interface associated with the LPDDR device.

Aspect 20: An apparatus, comprising: means for generating a clock signal for a memory interface; means for applying, to the clock signal, a clock leveling to one or more initial clock pulses associated with the clock signal; and means for stopping the clock leveling for one or more remaining clock pulses associated with the clock signal.

Aspect 21: A system configured to perform one or more operations recited in one or more of Aspects 1-20.

Aspect 22: An apparatus comprising means for performing one or more operations recited in one or more of Aspects 1-20.

Aspect 23: A non-transitory computer-readable medium storing a set of instructions, the set of instructions comprising one or more instructions that, when executed by a device, cause the device to perform one or more operations recited in one or more of Aspects 1-20.

Aspect 24: A computer program product comprising instructions or code for executing one or more operations recited in one or more of Aspects 1-20.

The foregoing disclosure provides illustration and description but is not intended to be exhaustive or to limit the implementations to the precise forms disclosed. Modifications and variations may be made in light of the above disclosure or may be acquired from practice of the implementations described herein.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A device, comprising:
one or more components configured to:
generate a clock signal for a memory interface;
apply a clock leveling to one or more initial clock pulses associated with the clock signal; and
stop the clock leveling for one or more remaining clock pulses associated with the clock signal.

2. The device of claim 1, wherein the clock leveling reduces a peak voltage level associated with the clock signal to allow a faster zero crossing for the clock signal, as compared to when the peak voltage level is not reduced using the clock leveling, and wherein the faster zero crossing reduces or removes a clock pulse distortion associated with the one or more initial clock pulses.

3. The device of claim 1, wherein the one or more components, to apply the clock leveling, are configured to:
depress a voltage level associated with the clock signal during the one or more initial clock pulses, and wherein an amount of the voltage level depression is associated with an amount of de-emphasis.

4. The device of claim 1, wherein the one or more components are configured to:
stop the clock leveling in accordance with a window for leveling shutoff.

5. The device of claim 1, wherein the one or more components, to stop the clock leveling, are configured to:
detect, using a detector, an edge associated with the clock signal; and
stop the clock leveling, after the edge, during a pulse high or a pulse low associated with the clock signal.

6. The device of claim 1, wherein the clock leveling is applied to only a first clock pulse associated with the clock signal, and wherein the clock leveling is not applied to remaining clock pulses associated with the clock signal.

7. The device of claim 1, wherein the clock leveling is applied at a transmitter of the device, and the clock leveling reduces duty cycle distortion at a receiver of the device.

8. The device of claim 1, wherein the clock signal is a true clock signal.

9. The device of claim 1, wherein the clock signal is a complementary clock signal.

10. The device of claim 1, wherein the device is a low power double data rate (LPDDR) device, and wherein the clock leveling is applied to an LPDDR memory interface associated with the LPDDR device.

11. A method, comprising:
generating, by a device, a clock signal for a memory interface;
applying, by the device, a clock leveling to one or more initial clock pulses associated with the clock signal; and
stopping, by the device, the clock leveling for one or more remaining clock pulses associated with the clock signal.

12. The method of claim 11, wherein the clock leveling reduces a peak voltage level associated with the clock signal to allow a faster zero crossing for the clock signal, as compared to when the peak voltage level is not reduced using the clock leveling, and wherein the faster zero crossing reduces or removes a clock pulse distortion associated with the one or more initial clock pulses.

13. The method of claim 11, wherein applying the clock leveling comprises:
depressing a voltage level associated with the clock signal during the one or more initial clock pulses, and wherein an amount of the voltage level depression is associated with an amount of de-emphasis.

14. The method of claim 11, wherein stopping the clock leveling is in accordance with a window for leveling shutoff.

15. The method of claim 11, wherein stopping the clock leveling comprises:
detecting, using a detector, an edge associated with the clock signal; and
stopping the clock leveling, after the edge, during a pulse high or a pulse low associated with the clock signal.

16. The method of claim 11, wherein the clock leveling is applied to only a first clock pulse associated with the clock signal, and wherein the clock leveling is not applied to remaining clock pulses associated with the clock signal.

17. The method of claim 11, wherein the clock leveling is applied at a transmitter of the device, and the clock leveling reduces duty cycle distortion at a receiver of the device.

18. The method of claim 11, wherein:
the clock signal is a true clock signal; or
the clock signal is a complementary clock signal.

19. The method of claim 11, wherein the device is a low power double data rate (LPDDR) device, and wherein the clock leveling is applied to an LPDDR memory interface associated with the LPDDR device.

20. An apparatus, comprising:
means for generating a clock signal for a memory interface;
means for applying, to the clock signal, a clock leveling to one or more initial clock pulses associated with the clock signal; and
means for stopping the clock leveling for one or more remaining clock pulses associated with the clock signal.
